(19) United States
(12) Patent Application Publication
(10) Pub. No.: US 2026/0118387 A1
(43) Pub. Date: Apr. 30, 2026

(54) UTILITY METER WITH ENHANCED CLOCK ACCURACY

(71) Applicant: EI ELECTRONICS LLC, D/B/A ELECTRO INDUSTRIES/GAUGE TECH, Westbury, NY (US)

(72) Inventor: Jorge A. Polar Seminario, Westbury, NY (US)

(21) Appl. No.: 19/374,347

(22) Filed: Oct. 30, 2025

Related U.S. Application Data
(60) Provisional application No. 63/714,469, filed on Oct. 31, 2024.

(51) Int. Cl. G01R 11/185; G01R 22/06; G01R 22/10

(52) U.S. Cl. CPC G01R 11/185; G01R 22/063; G01R 22/10

(57) ABSTRACT

An electronic power meter for monitoring power usage of an electrical circuit includes a housing and at least one sensor connected to the housing and configured to be connected to an electrical circuit. The at least one sensor is configured for measuring at least one power parameter of the electrical circuit and processing system is configured to receive the measured data and create a calculated data. The processing system includes a real time clock emitting a clock signal and a temperature sensor emitting a temperature signal. The processing system is configured to analyze the clock signal and the temperature signal to detect a deviation in the clock signal and to apply a trim value to the clock signal if a deviation is detected to obtain a corrected time data.

### RELATED APPLICATION(S)

This application is based on U.S. Provisional Application Serial No. 63/714,469, filed October 31, 2024, the disclosure of which is incorporated herein by reference in its entirety and to which priority is claimed.

### FIELD

The present disclosure is directed to intelligent electronic devices for utility systems, such as smart meters that can record and communicate utility usage information.

### BACKGROUND

Monitoring of electrical energy by consumers and providers of electric power is a fundamental function within any electric power distribution system. Electrical energy may be monitored for purposes of usage, equipment performance and power quality. Electrical parameters that may be monitored include volts, amps, watts, vars, power factor, harmonics, kilowatt hours, kilovar hours and any other power related measurement parameters. Typically, measurement of the voltage and current at a location within the electric power distribution system may be used to determine the electrical parameters for electrical energy flowing through that location.

Devices that perform monitoring of electrical energy may be electromechanical devices, such as, for example, a residential billing meter or may be an intelligent electronic device (“IED”). Intelligent electronic devices typically include some form of a processor. In general, the processor is capable of using the measured voltage and current to derive the measurement parameters. The processor operates based on a software configuration. A typical consumer or supplier of electrical energy may have many intelligent electronic devices installed throughout their operations. IEDs may be positioned along the supplier's distribution path or within a customer's internal distribution system. IEDs include revenue electric watt-hour meters, protection relays, programmable logic controllers, remote terminal units, fault recorders and other devices used to monitor and/or control electrical power distribution and consumption. IEDs can make use of memory and microprocessors to provide increased versatility and additional functionality. Such functionality includes the ability to communicate with remote computing systems, either via a direct connection, e.g., a modem, a wireless connection or a network. IEDs can also include legacy mechanical or electromechanical devices that have been retrofitted with appropriate hardware and/or software allowing integration with the power management system.

Typically, an IED is associated with a particular load or set of loads that are drawing electrical power from the power distribution system. The IED may also be capable of receiving data from or controlling its associated load. Depending on the type of IED and the type of load it may be associated with, the IED implements a power management function that is able to respond to a power management command and/or generate power management data. Power management functions include measuring power consumption, controlling power distribution such as a relay function, monitoring power quality, measuring power parameters such as phasor components, voltage or current, controlling power generation facilities, computing revenue, controlling electrical power flow and load shedding, or combinations thereof.

Conventional IEDs include the ability to communicate with remote computing systems. Traditionally, IEDs would transfer data using serial based download commands. These commands would be accessed via an RS232, and RS485 or an Ethernet port encapsulating the serial request with an Ethernet message using any Ethernet protocol such as HTTP or TCP/IP. For instance, host software or a primary would make a request for a set of data from one or more memory registers in an IED secondary device. At that point, the IED secondary would then communicate the data stored in the memory registers back to the host software utilizing a serial transfer. A need exists for systems and methods for efficiently collecting data from various devices, e.g., IEDs. A further need exists for systems and methods for analyzing and reporting such collected data.

### SUMMARY

In certain implementations, a utility meter is provided with firmware that compensates for inaccuracies caused by temperature drift in an internal oscillator for the real time clock.

In certain implementations, a utility meter is provided with that utilizes only an internal clock signal with compensation for inaccuracies corrected by internal components and software.

In certain configurations, an electronic power meter for monitoring power usage of an electrical circuit includes a housing and at least one sensor connected to the housing and configured to be connected to an electrical circuit. The at least one sensor is configured for measuring at least one power parameter of the electrical circuit and a processing system is configured to receive the measured data and create a calculated data. The processing system includes a real time clock emitting a clock signal and a temperature sensor emitting a temperature signal. The processing system is configured to analyze the clock signal and the temperature signal to detect a deviation in the clock signal and to apply a trim value to the clock signal if a deviation is detected to obtain a corrected time data.

In certain configurations, an electronic power meter for monitoring power usage of an electrical circuit includes a housing and at least one sensor connected to the housing and configured to be connected to the electrical circuit. The at least one sensor is configured for measuring at least one power parameter of the electrical circuit and generating at least one analog signal indicative of the at least one power parameter. At least one analog to digital converter is connected to the at least one sensor. The at least one analog to digital converter is configured to receive the at least one analog signal and convert the at least one analog signal to an at least one digital signal to obtain measured data. A processing system including one or more processors is configured for receiving the at least one digital signal and performing at least one calculation based on the received at least one digital signal to obtain calculated data. Memory is connected to the processing system. The memory includes at least one memory location. The memory is configured to store the measured data and the calculated data. The processing system includes a real time clock emitting a clock signal and a temperature sensor emitting a temperature signal. The processing system is configured to analyze the clock signal and the temperature signal to detect a deviation in the clock signal and to apply a trim value to the clock signal if a deviation is detected to obtain a corrected time data.

### BRIEF DESCRIPTION OF THE DRAWINGS

The aspects and features of various exemplary embodiments will be more apparent from the description of those exemplary embodiments taken with reference to the accompanying drawings.

FIG. 1 is a block diagram of an intelligent electronic device (IED).

FIG. 2 is a flow chart for a shadow clock process used to enhance internal clock accuracy.

FIG. 3 is a flow chart for a clock locking process used to enhance internal clock accuracy.

FIG. 4 is a schematic diagram of a configuration of circuit components of the clock locking process.

FIG. 5 is a schematic diagram of another configuration of circuit components of the clock locking process.

### DETAILED DESCRIPTION OF EXEMPLARY EMBODIMENTS

In certain implementations, intelligent electronic devices (“IEDs”) can be used for power monitoring to sense electrical parameters and compute data. IEDs can be any device or combination of devices including, but not limited to, Programmable Logic Controllers (“PLC's”), Remote Terminal Units (“RTU's”), electric power meters, panel meters, protective relays, fault recorders, phase measurement units, serial switches, smart input/output devices and other devices which are coupled with power distribution networks to manage and control the distribution and consumption of electrical power. A power meter is a device that records and measures power events, power quality, current, voltage waveforms, harmonics, transients and other power disturbances. Revenue accurate meters (“revenue meter”) relate to revenue accuracy electrical power metering devices with the ability to detect, monitor, report, quantify and communicate power quality information about the power that they are metering.

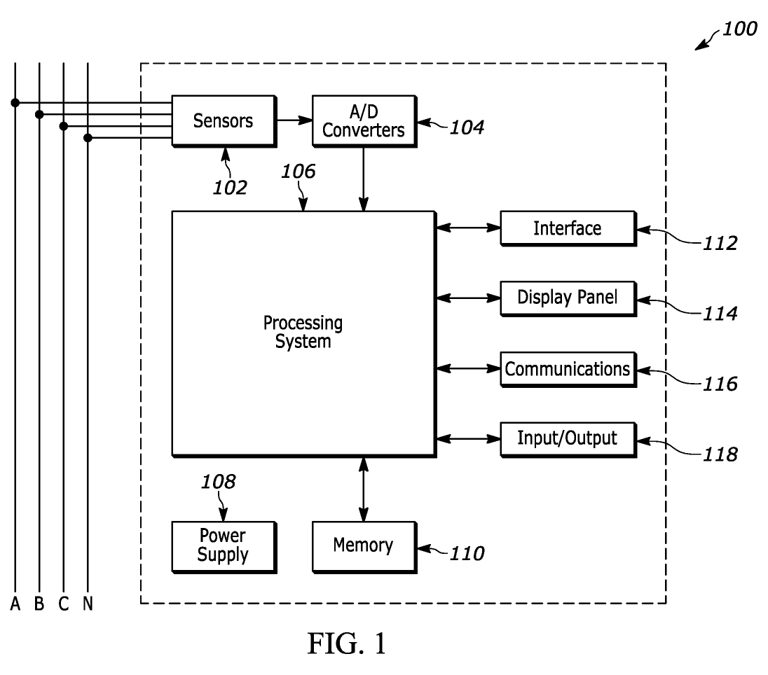

FIG. 1 shows an exemplary configuration of an IED 100 having a plurality of sensors 102 connected to various phases A, B, C and neutral N of an electrical distribution system. One or more analog-to-digital (A/D) converters 104 can be connected to the sensors and connect the sensors 102 to a processing system 106. The processing system 106 can include any combination of processing components including, a CPU, microcontroller, digital signal processors, field programmable gate arrays, programmable logic device, etc. The IED 100 can include a power supply 106 to supply power to the various components. One or more memory units 110 is connected to the processing system 106. The processing system 106 can be in communication with a user interface 112, a display panel 114, a communication interface 116, and one or more input/output ports 118.

The plurality of sensors 102 sense electrical parameters, e.g., voltage and current, on incoming lines, (i.e., phase A, phase B, phase C, neutral N), from an electrical power distribution system. In certain configurations, the sensors 102 can include current transformers and potential transformers, wherein one current transformer and one voltage transformer will be coupled to each phase of the incoming power lines. A primary winding of each transformer will be coupled to the incoming power lines and a secondary winding of each transformer will output a voltage representative of the sensed voltage and current.

The output of each transformer will be coupled to the A/D converters 104 configured to convert the analog output voltage from the transformer to a digital signal that can be processed by the processing system 106. A/D converters 104 are respectively configured to convert an analog voltage output to a digital signal that is transmitted to the processing system 106 to be processed. The processing system 106 is configured to operatively receive digital signals from the A/D converters 104 and to perform calculations necessary to determine power usage and to control the overall operations of the IED 100.

The power supply 108 provides power to each component of the IED 100. In certain configurations, the power supply 108 is a transformer with its primary windings coupled to the incoming power distribution lines and having windings to provide a nominal voltage, e.g., 5 VDC, +12 VDC and −12 VDC, at its secondary windings. In other configurations, power may be supplied from an independent power source to the power supply 108. For example, power may be supplied from a different electrical circuit or an uninterruptible power supply (UPS). In other configurations, the power supply can be a DC power supply such as a battery or rechargeable battery.

In some configurations, the power supply 108 can be a switch mode power supply in which the primary AC signal will be converted to a form of DC signal and then switched at high frequency, such as, for example, 100 Khz, and then brought through a transformer to step the primary voltage down to, for example, 5 Volts AC. A rectifier and a regulating circuit would then be used to regulate the voltage and provide a stable DC low voltage output. Other embodiments, such as, but not limited to, linear power supplies or capacitor dividing power supplies are also contemplated.

The IED 100 further comprises a memory unit 110 which can include one or more memory components, such as volatile memory and non-volatile memory. In addition to storing audio and/or video files, memory 110 can store the sensed and generated data for further processing and for retrieval when called upon to be displayed at the IED 100 or from a remote location. The memory 110 can include any combination of: internal storage memory, e.g., random access memory (RAM); removable memory such as magnetic storage memory; optical storage memory, e.g., the various types of CD and DVD media; solid-state storage memory, e.g., a CompactFlash card, a Memory Stick, SmartMedia card, MultiMediaCard (MMC), SD (Secure Digital) memory; or any other memory storage that exists currently or will exist in the future. By utilizing removable memory, an IED can be easily upgraded as needed. Such memory will be used for storing historical trends, waveform captures, event logs including time-stamps and stored digital samples for later downloading to a client application, web-server or PC application.

The user interface 112 is connected to the processing system 106 for interacting with a user and for communicating events, such as alarms and instructions to the user. The interface 112 may include any set of physical inputs, such as buttons, touch screens, dials, etc. The user interface 112 further includes a speaker or audible output means for audibly producing instructions, alarms, data, etc. The speaker is coupled to the processing system 106 via a digital-to-analog converter (D/A) for converting digital audio files stored in memory 110.

The IED 100 can also include a display 114 for providing visual indications to the user. The display may be embodied as a touch screen, a liquid crystal display (LCD), a plurality of LED number segments, individual light bulbs or any combination. The display 114 can provide information to the user in the form of alpha-numeric lines, computer-generated graphics, videos, animations, etc. The IED 100 can also support various multimedia file types as needed, including video, audio, and image file types.

In certain implementations, the IED 100 will include a communication device 116, also known as a network interface, for enabling communications between the IED or meter, and a remote terminal unit, programmable logic controller and other computing devices, microprocessors, a desktop computer, laptop computer, other meter modules, etc. The communication device 116 can be a modem, network interface card (NIC), wireless transceiver, etc. The communication device 116 will perform its functionality by hardwired and/or wireless connectivity. The hardwire connection may include but is not limited to hard wire cabling e.g., parallel or serial cables, RS232, RS485, USB cable, Firewire (1394 connectivity) cables, Ethernet, and the appropriate communication port configuration. The wireless connection will operate under any of the various wireless protocols including but not limited to Bluetooth™ interconnectivity, infrared connectivity, radio transmission connectivity including computer digital signal broadcasting and reception commonly referred to as Wi-Fi or 802.11.X (where x denotes the type of transmission), satellite transmission or any other type of communication protocols, communication architecture or systems currently existing or to be developed for wirelessly transmitting data including spread spectrum 900 MHz, or other frequencies, Zigbee, WiFi, or any mesh enabled wireless communication.

The IED 100 can communicate to a server or other computing device via the communication device 116. The IED 100 can be connected to a communications network, e.g., the Internet, by any means, for example, a hardwired or wireless connection, such as dial-up, hardwired, cable, DSL, satellite, cellular, PCS, wireless transmission (e.g., 802.11a/b/g), etc. It is to be appreciated that the network may be a local area network (LAN), wide area network (WAN), the Internet or any network that couples a plurality of computers to enable various modes of communication via network messages. Furthermore, the server will communicate using various protocols such as Transmission Control Protocol/Internet Protocol (TCP/IP), File Transfer Protocol (FTP), Hypertext Transfer Protocol (HTTP), etc. and secure protocols such as Hypertext Transfer Protocol Secure (HTTPS), Internet Protocol Security Protocol (IPSec), Point-to-Point Tunneling Protocol (PPTP), Secure Sockets Layer (SSL) Protocol, etc. The server will further include a storage medium for storing a database of instructional videos, operating manuals, etc., the details of which will be described in detail below.

In an additional configuration, the IED 100 can also have the capability of not only digitizing waveforms, but storing the waveform and transferring that data upstream to a central computer, e.g., a remote server, when an event occurs such as a voltage surge or sag or a current short circuit. This data will be triggered and captured on an event, stored to memory, e.g., non-volatile RAM, and additionally transferred to a host computer within the existing communication infrastructure either immediately in response to a request from a remote device or computer to receive said data in response to a polled request. The digitized waveform will also allow the processing system 106 to compute other electrical parameters such as harmonics, magnitudes, symmetrical components and phasor analysis. Using the harmonics, the IED 100 will also calculate dangerous heating conditions and can provide harmonic transformer derating based on harmonics found in the current waveform.

In a further configuration, the IED 100 can execute an e-mail client and will send e-mails to the utility or to the customer direct on an occasion that a power quality event occurs. This allows utility companies to dispatch crews to repair the condition. The data generated by the meters are used to diagnose the cause of the condition. The data is transferred through the infrastructure created by the electrical power distribution system. The email client will utilize a POP3 or other standard mail protocol. A user will program the outgoing mail server and email address into the meter.

The techniques of the present disclosure can be used to automatically maintain program data and provide field wide updates upon which IED firmware and/or software can be upgraded. An event command can be issued by a user, on a schedule or by digital communication that will trigger the IED 100 to access a remote server and obtain the new program code. This will ensure that program data will also be maintained allowing the user to be assured that all information is displayed identically on all units.

It is to be understood that the present disclosure may be implemented in various forms of hardware, software, firmware, special purpose processors, or a combination thereof. The IED 100 also includes an operating system and micro instruction code. The various processes and functions described herein may either be part of the micro instruction code or part of an application program (or a combination thereof) which is executed via the operating system.

It is to be further understood that because some of the constituent system components and method steps depicted in the accompanying figures may be implemented in software, or firmware, the actual connections between the system components (or the process steps) may differ depending upon the manner in which the present disclosure is programmed. Given the teachings of the present disclosure provided herein, one of ordinary skill in the related art will be able to contemplate these and similar implementations or configurations of the present disclosure.

The components and devices of the IED 100 can be positioned in various depending on the application or working environment. For example, the components can be positioned in a panel meter, socket meter, switchboard or draw-out type housing, A-base or type A housing. Other housings and mounting schemes are within the scope of this disclosure.

Additionally, the IED 100 can be implanted in various environments. For example, the IED 100 can be implemented in a network, such as public or private network, WAN, LAN, or other type of network. The IED 100 can be connected over the network to various other devices, such as through client/server networks, peer-to-peer networks, mesh networks, etc.

Examples of certain housings, environments, and other features that can be incorporated in the IED 100 are shown and described in U.S. Published Application 2020/0012488, the contents of which are hereby incorporated by reference in their entirety.

In certain implementations, the processing system 106 can include an internal clock that generates a clock signal used by the processing system 106. The clock can be used to process system functions and also to determine power readings, such as to provide a time for computing energy consumed by a load over a given period of time.

In certain configurations, the internal clock can include an internal oscillator. An internal oscillator can be efficient for initial costs and power consumption, but can have reduced accuracy, especially with relation to swings in operating temperature, which can cause frequency drifts due to temperature instability.

In certain configurations, an external real time clock can be used to provide a clock signal to the processing system 106 in place of, or in addition to, an internal clock. An external real time clock can help to provide an accurate clock signal even if there is a loss of internal power to the unit. External real time clocks, however, need to be accessed by the processing system 106. This can add latency due to the communication time.

In certain implementations, the external real time clock can be used as a shadow clock, using its time base for the internal clock keeping the progress of the time counters (minute, seconds, etc.) accurate. All the read and write actions of time are performed mainly in the internal real time clock but they are also shadow copied to the external clock because the external is non-volatile (if power fails the external keeps counting).

In some implementations, the external clock can be written one second after the internal is written (scheduled writing) taking advantage of and internal interrupt that occurs at the top of every second. The external clock can therefore be synchronized to the internal with the latency (800 - 4000 us) and it is used only as a backup (in case the main unit loses energy).

If power fails, once the main processor comes online, it will refresh its internal time from the external real time clock even with the uncertainty latency, and later the internal real time clock is updated more accurately by means of NTP (network time protocol), IRIG or other synchronization methods. The update of the external real time clock can happen in the background and it always has a small latency as a projection of the main internal real time clock.

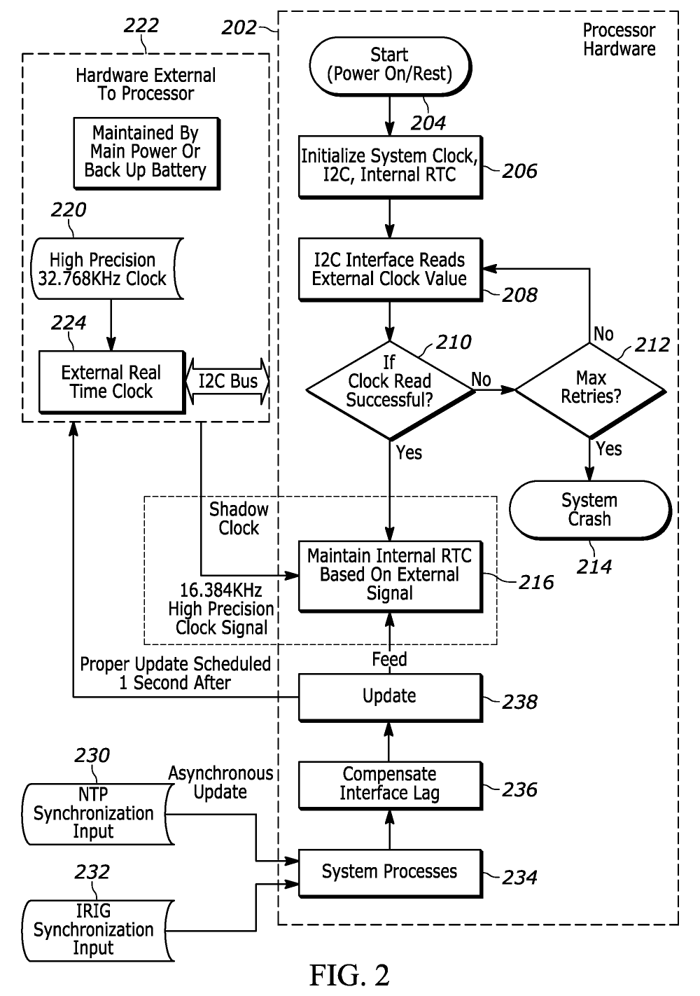

FIG. 2 shows an exemplary implementation of a shadow clock system. One or more processors 202 are started 204 and go through an initialization process 206. The initialization process 206 can initialize the system clock, the Inter-Integrated Circuit (I2C) bus, and the internal real time clock. The I2C interface will then attempt to read the external clock value 208. A determination is made if the clock read was successful 210. If the clock read is unsuccessful, a set number of retries is initiated 212 before a system crash 214. If the clock read is successful, the internal real time clock is based on the external real time clock signal 216.

The external real time clock 220 can be positioned on a hardware unit 222 external to the one or more processors 202. The external real time clock 220 can be a high precision clock configured to output a clock signal 224. The external real time clock 220 can be maintained by a normal power source and a backup battery.

The one or more processors 202 are also in communication with an NTP input 230 and IRIG input 232 or a combination of both. The NTP input 230 and the IRIG input 232 are processed by the system 234 and a compensation for the interface lag is implemented 236. A time signal update 238 is created and can be pushed to the external clock 220 and to the internal time signal. In this system, data can be logged using the internal clock with the external clock as a backup.

In certain implementations, the need for an external real time clock can be eliminated by implementing a clock locking process that compensates for inaccuracies caused by temperature drift in the internal oscillator. This process can be achieved using firmware, eliminating the need for extra hardware components.

In certain applications component costs can be reduced by using an internal oscillator for feeding the main processor system. The internal oscillator, however, can have a coarse accuracy that is not stable enough within the range of operational temperatures for devices such as utility meters. To enhance the internal oscillator accuracy, a firmware lock can be implemented between the real time clock and the internal oscillator. The Real time clock is very accurate and stable, so the firmware can use this clock as a base time and measures the internal processor oscillator frequency in regular intervals. The system will also measure the operating temperature, for example using a temperature sensor such as a board mounted thermistor. When temperature changes by a certain amount, for example by 5 degrees Celsius, an error correction can be computed for the internal oscillator. The firmware computes a compensation value and feeds this value into a trimming circuit in the processor to adjust the internal oscillator. The process is repeated several times, and a lookup table is built on the fly. After 5 iterations the internal oscillator is calibrated to the expected frequency and is continuously monitored as temperature and time varies. The lookup table can be used immediately after power up, so every time the meter is turned on or reset the adjusting process is faster.

In certain implementations, it can be required or desirable to eliminate the external real time clock shown in FIG. 2 and thus to eliminate the shadow clock. In such instances, it can be necessary to increase the internal clock accuracy, as most internal clocks are susceptible to drift, especially when units are exposed to temperature variations.

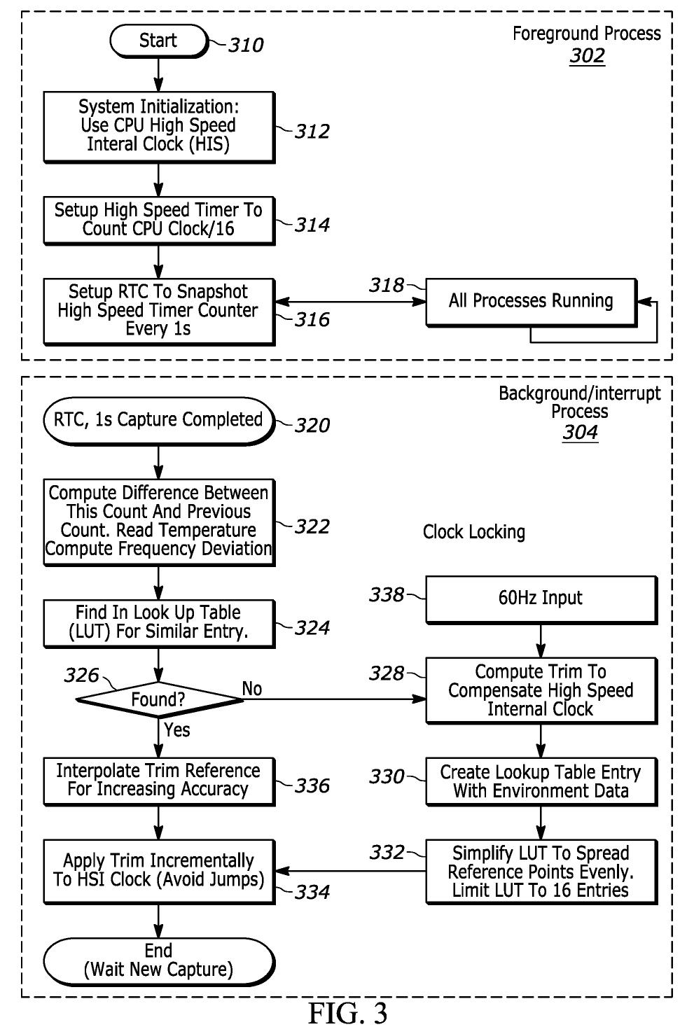

FIG. 3 shows an exemplary implementation of a clock locking system utilizing a foreground process 302 and a background process 304. In the foreground process 302, after startup 310 the system initializes 312, using the high-speed internal oscillator clock. The oscillator signal can be synced to a CPU clock 314. The real time clock snapshots the high-speed timer counter at certain intervals 316, for example every second, and the time can be sent to the running processes 318, for example to be associated with utility meter readings and stored with data in memory as appropriate.

In the background process 304, once a real time clock snapshot is completed 320, the difference between the current count and the previous count is computed and a temperature reading is taken to compute a frequency deviation 322. This can help to determine if there is any drift in the time by the internal oscillator. A lookup table is checked to determine if there is a similar frequency deviation entry 324 and a decision is made if a similar entry is available 326 within a specific range or tolerance. If a similar entry is not found, the one or more processors can compute a trim value to compensate for the drift in the internal clock 328. Based on this calculation, a lookup table entry is created which can include the environmental data (e.g., temperature reading or temperature change) 330 to create a reference point. The lookup table can be consistently managed 332, for example to spread the reference points out evenly and to limit the lookup table to a certain number of entries. In certain implementations, spreading the reference points evenly can be based on the lowest and highest reference point. In certain implementations, the number of entries can be limited to 16.

The trim value can then be applied to the high-speed internal clock signal to avoid any jumps in timing 334. In future iterations, if a related entry is found the entry can be interpolated 336 and applied 334 to increase the clock accuracy and speed of operation.

A trim value can be applied to create a corrected time data which can then be applied to the calculated data or measured data obtained by the meter or IED 100 and the processing system 106. The processing system can use the corrected time data to create time-stamped data entries which are stored in memory 110. If no correction is needed, the original time data can be applied to create the time-stamped data.

In this way, any inconsistencies in the internal clock can be compensated using a limited number of internal hardware components and software as opposed to external components or other external signals. This can also allow for a coarser internal clock to be used in applications where high accuracy internal clocks would be too expensive or have a reduced life due to environmental conditions.

In certain configurations, a frequency input 338 can be applied to the trim calculation to help compensate for clock inaccuracies. The frequency input can be used to create a timing signal calculated by the processing system 106 based on an input from the sensors 102. For example, the processing system 106 can include, or be connected to, a circuit that determines when one or more of the frequency waves from the three-phase power supply crosses zero (going from negative to positive or positive to negative). When the wave crosses zero, a signal can be output by the circuit. The processing system 106 can track the signal output, with each signal representing a certain time interval depending on the frequency. This output can be used to keep a reliable track of time to assist in the trim calculation of the circuit.

In certain configurations, the frequency input can be a 60 Hz input from a US standard power gird. In such configurations, each output signal can represent 1/120th of a second. This output can be calculated to keep track of seconds in certain time intervals when the meter is operation. Other configurations can use other calculations based on different locations, for example a 50 Hz frequency used in Europe.

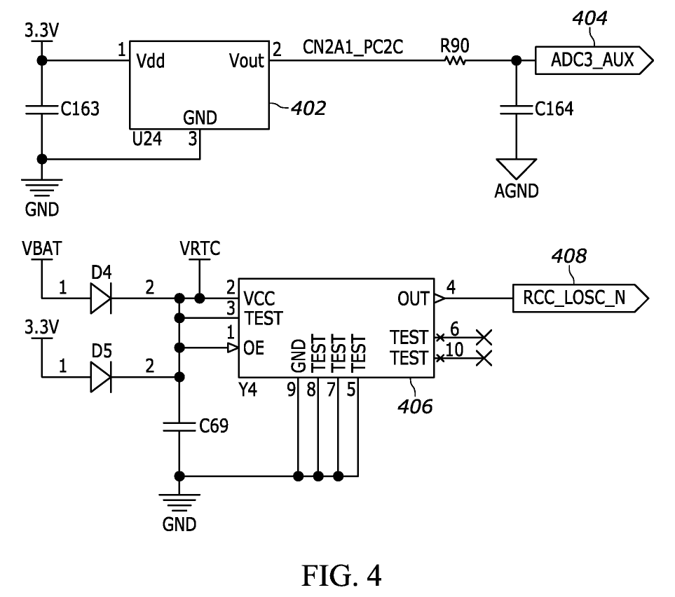

FIG. 4 shows a configuration of circuit components that can be used in the processing system 106 to perform the clock locking process. The components can include a temperature sensor circuit 402 having an analog signal output 404 to an analog/digital converter. The analog/digital converter can output a signal to one or more processors of the processing system 106. An oscillator 406 can be used as the internal real time clock which provides a clock signal output 408 to one or more processors of the processing system 106. The oscillator 406 can be an RC, LC, or other type of oscillator. The temperature output 404 and the clock signal 408 can be used as the inputs for the background process 304 to search and, if necessary, build the lookup table.

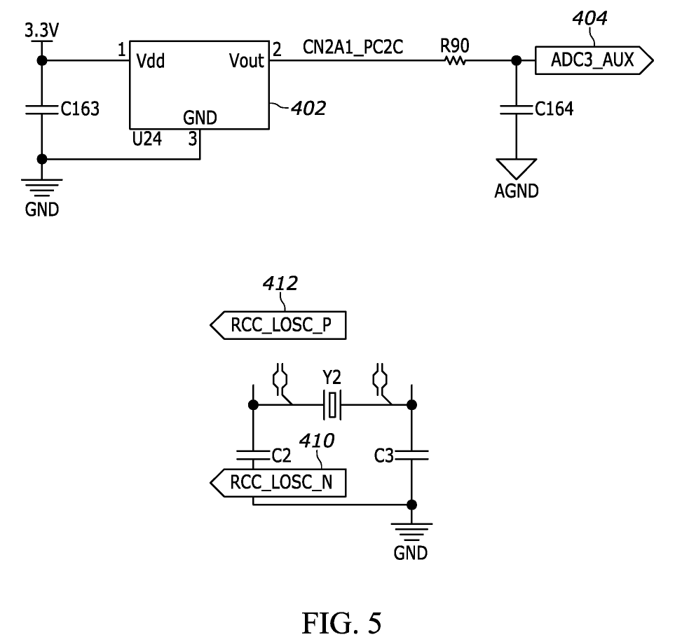

FIG. 5 shows another configuration of the components that can be used in the processing system 106 to perform the clock locking procedure. Instead of the oscillator 406, a crystal oscillator is used to provide the clock signal output 412 to the one or more processors of the processing system 106. The temperature output 404 and the clock signal 412 can be used as the inputs for the background process 304 to search and, if necessary, build the lookup table.

The foregoing detailed description has been provided for the purpose of explaining the general principles and practical application, thereby enabling others skilled in the art to understand the disclosure for various configurations and implementations, and with various modifications as are suited to the particular uses contemplated. This description is not necessarily intended to be exhaustive or to limit the disclosure to what is disclosed. Any of the configurations and/or elements disclosed herein may be combined with one another to form various additional embodiments not specifically disclosed. Accordingly, additional configurations and implementations are possible and are intended to be encompassed within this specification and the scope of the appended claims. The specification describes specific examples to accomplish a more general goal that may be accomplished in another way.

As used in this application, the terms “front,” “rear,” “upper,” “lower,” “upwardly,” “downwardly,” and other orientational descriptors are intended to facilitate the description of the exemplary embodiments of the present disclosure, and are not intended to limit the structure of the exemplary embodiments of the present disclosure to any particular position or orientation. Terms of degree, such as “substantially” or “approximately” are understood by those of ordinary skill to refer to reasonable ranges outside of the given value, for example, general tolerances associated with manufacturing, assembly, and use of the described embodiments. Unless specified or limited otherwise, the terms “mounted,” “connected,” “supported,” and “coupled” and variations thereof are used broadly and encompass both direct and indirect mountings, connections, supports, and couplings. The words “member,” “component,” “module,” “mechanism,” “element,” “device,” and the like are not a substitute for the word “means.” As such, no claim element should be construed as a means plus function unless the element is expressly recited using the phrase “means for.”

Functionality described herein may be implemented by any combination of hardware, software, or firmware. Functionality described herein as being performed by one component may be performed by multiple components in a distributed manner. Likewise, functionality performed by multiple components may be consolidated and performed by a single component. Similarly, a component described as performing particular functionality may also perform additional functionality not described herein. For example, a device or structure that is “configured” in a certain way is configured in at least that way but may also be configured in ways that are not explicitly listed.

Certain electrical components are generally shown and described in terms of their functions or end results as it would be understood by one of ordinary skill viewing this disclosure that the exact structure, connections, and components can be varied to achieve the desired results. In addition, certain implementation may include hardware, software, and electronic components or modules that, for purposes of discussion, may be illustrated and described as if most of the components were implemented solely in hardware. However, one of ordinary skill in the art, and based on a reading of this disclosure would recognize that in certain configurations the electronic-based aspects may be implemented in software (e.g., stored on non-transitory computer-readable medium) executable by one or more processing units, such as any combination of one or more of a general-purpose processor, microprocessor, DSP, FPGA, application specific integrated circuits (“ASICs”), and/or other programmable logic device.. As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

What is claimed:

1. An electronic power meter for monitoring power usage of an electrical circuit comprising:
a housing;
at least one sensor connected to the housing and configured to be connected to an electrical circuit, the at least one sensor configured for measuring at least one power parameter of the electrical circuit and generating at least one analog signal indicative of the at least one power parameter;
at least one analog to digital converter connected to the at least one sensor, the at least one analog to digital converter configured to receive the at least one analog signal and convert the at least one analog signal to an at least one digital signal to obtain measured data;
a processing system including one or more processors, the processing system configured for receiving the at least one digital signal and performing at least one calculation based on the received at least one digital signal to obtain calculated data;
memory connected to the processing system, the memory comprising at least one memory location, the memory configured to store the measured data and the calculated data,
wherein the processing system includes a real time clock emitting a clock signal and a temperature sensor emitting a temperature signal, and wherein the processing system is configured to analyze the clock signal and the temperature signal to detect a deviation in the clock signal and to apply a trim value to the clock signal if a deviation is detected to obtain a corrected time data.

2. The electronic power meter of claim 1, wherein the processing system is configured to compare the clock signal and the temperature signal to a lookup table stored in the memory.

3. The electronic power meter of claim 2, wherein the processing system is configured to determine if there is a related entry in the lookup table relative to the clock signal and temperature signal and apply the trim value of the related entry.

4. The electronic power meter of claim 2, wherein the processing system is configured to determine if there is a related entry in the lookup table relative to the clock signal and temperature signal and to calculate a new trim value if no related entry is found.

5. The electronic power meter of claim 4, wherein the processing system is configured to save the new trim value in the lookup table.

6. The electronic power meter of claim 5, wherein the processing system is configured to manage the trim values in the lookup table to keep them at a set number.

7. The electronic power meter of claim 5, wherein the processing system is configured to manage the trim values in the lookup table to spread the trim values out evenly.

8. The electronic power meter of claim 1, wherein the real time clock includes a crystal oscillator.

9. The electronic power meter of claim 1, wherein the processing system is configured to receive a frequency input from the electrical circuit and utilize the frequency input to calculate the trim value.

10. The electronic power meter of claim 9, wherein the frequency input is a 60 Hz input.

11. The electronic power meter of claim 1, wherein the processing system is configured to apply the corrected time data to calculated data to obtain time-stamped data and to save the time-stamped data in the memory.

12. A method of applying a time value to a data record in an electronic power meter for monitoring power usage of an electrical circuit comprising:
measuring at least one power parameter of an electrical circuit and generating at least one analog signal indicative of the at least one power parameter;
receiving the at least one analog signal by a digital to analog converter and converting the at least one analog signal to an at least one digital signal to obtain measured data;
receiving, by a processing system including one or more processors, the at least one digital signal and performing at least one calculation based on the received at least one digital signal to obtain calculated data;
receiving, by the processing system, a clock signal emitted by an internal real time clock;
receiving, by the processing system, a temperature signal emitted by an internal temperature sensor;
determining, based in least in part on the clock signal and the temperature signal, a deviation in the clock signal;
applying trim value to the clock signal if a deviation is detected to create a corrected time value;
applying the corrected time value to the calculated data to obtain time-stamped data; and
storing the time-stamped data in memory connected to the processing system.

13. The method of claim 12, further comprising comparing the clock signal and the temperature signal to a lookup table stored in the memory.

14. The method of claim 13, further comprising determining if there is a related entry in the lookup table relative to the clock signal and temperature signal and applying the trim value of the related entry.

15. The method of claim 13, further comprising determining if there is a related entry in the lookup table relative to the clock signal and temperature signal and calculating a new trim value if no related entry is found.

16. The method of claim 15, further comprising saving the new trim value in the lookup table.

17. The method of claim 16, further comprising managing the trim values in the lookup table to keep them at a set number.

18. The method of claim 16, further comprising managing the trim values in the lookup table to spread the trim values out evenly.

19. The method of claim 12, further comprising receiving a frequency signal from the electrical circuit and utilizing the frequency signal to calculate the trim value.

20. The method of claim 19, wherein the frequency signal is a 60 Hz frequency signal.
